(19) United States
(12) Patent Application Publication
(10) Pub. No.: US 2024/0321997 A1
(43) Pub. Date: Sep. 26, 2024

(54) SEMICONDUCTOR STRUCTURE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventors: Hailong YU, Shanghai (CN); Xuezhen JING, Shanghai (CN); Jinhui MENG, Shanghai (CN)

(21) Appl. No.: 18/580,537

(22) PCT Filed: Jul. 20, 2021
(86) PCT No.: PCT/CN2021/107314

§ 371 Date: Jan. 18, 2024

(51) Int. Cl. H01L 29/49; H01L 29/06; H01L 29/40; H01L 29/417; H01L 29/423; H01L 29/775; H01L 29/786

(52) U.S. Cl. CPC H01L 29/4966; H01L 29/0673; H01L 29/401; H01L 29/41775; H01L 29/42392; H01L 29/775; H01L 29/78696

(57) ABSTRACT

A semiconductor structure and a method for forming a semiconductor structure are provided. The method includes: providing a substrate, where gate structures are formed on the substrate, source-drain doped regions are formed in the substrate on two sides of each gate structure, and a bottom dielectric layer between adjacent gate structures is formed on the source-drain doped regions; forming liner metal layers in contact with the gate structures on top surfaces of the gate structures, where the liner metal layers are made of a pure metal; forming a top dielectric layer on the bottom dielectric layer to cover the liner metal layers; and forming gate plugs penetrating through the top dielectric layer and in contact with the liner metal layers using a first selective deposition process.

### TECHNICAL FIELD

The present disclosure generally relates to the field of semiconductor fabrication technology and, more particularly, relates to a semiconductor structure and a fabrication method thereof.

### BACKGROUND

With the continuous development of integrated circuit manufacturing technology, people's requirements for the integration level and performance of integrated circuits are becoming higher and higher. To improve integration and reduce costs, the critical dimensions of components continue to become smaller, and the circuit density within integrated circuits becomes larger and larger. This development makes it impossible to provide enough area on wafer surfaces to fabricate required interconnect lines.

To meet the requirements of interconnection lines after critical dimensions have been reduced, conduction between different metal layers or between metal layers and substrates is achieved through interconnection structures. The interconnect structure includes interconnect lines and contact plugs formed within contact openings. The contact plugs are connected to a semiconductor device, and the interconnection lines realize the connection between the contact plugs, thereby forming a circuit. The contact plugs in transistor structures include gate contact plugs located on gate structures for connecting the gate structures to external circuits, and source-drain contact plugs located on source-drain doped regions for connection between the source-drain doped regions and the external circuits.

However, the performance of current devices still needs to be improved.

### Technical Problems

The preset disclosure provides a semiconductor structure and its fabrication method, to reduce the difficulty of forming gate plugs and improve the quality of the formed gate plugs.

### SUMMARY

To solve the above technical problems, the present disclosure provides a semiconductor structure. The semiconductor structure includes: a substrate; gate structures on the substrate; source-drain doped regions in the substrate on two sides of each gate structure; a bottom dielectric layer between adjacent gate structures and covering the source-drain doped regions; liner metal layers on top surfaces of the gate structures and in contact with the gate structures, where the liner metal layers are made of a material including a pure metal; a top dielectric layer on the bottom dielectric layer and covering the liner metal layers; and gate plugs, penetrating through the top dielectric layer and in contact with the liner metal layers.

Optionally, the liner metal layers are made of a material including W, Ru, or Mo.

Optionally, a thickness of the liner metal layers is about 1.5 nm to about 3 nm.

Optionally, the liner metal layers include chlorine element.

Optionally, the gate plugs are made of a material same as the liner metal layers.

Optionally, the gate plugs are made of a material including one or more of W or Ru.

Optionally, the gate structures are metal gate structures; and one metal gate structure includes a work function layer, or includes a metal electrode layer and a work function layer located on a bottom and sidewalls of the metal electrode layer.

Optionally, the work function layer is made of a material including one or more of TiA, TaAlN, TiAlN, MoN, TaCN, AlN, Ta, TiN, TaN, TaSiN, or TiSiN; and the metal electrode layer is made of a material including one or more of W, Al, Cu, Ag, Au, Pt, Ni, or Ti.

Optionally, the semiconductor structure further includes gate spacers on sidewalls of the gate structures; and gate dielectric layers between the gate structures and the substrate.

Optionally, the top dielectric layer includes: a first dielectric layer on the bottom dielectric layer and covering the liner metal layers; and a second dielectric layer on the first dielectric layer. The semiconductor structure further includes: source-drain interconnection layers which penetrate through the bottom dielectric layer and the first dielectric layer on tops of the source-drain doped regions, and are in contact with the source-drain doped region; and source-drain plugs, penetrating through the second dielectric layer and in contact with the source-drain interconnection layers.

Optionally, the substrate includes fins, wherein the gate structures cross the fins and the source-drain doped regions are located in the fins on two sides of each gate structure; or the substrate includes a channel structure layer, wherein the channel structure layer includes one or more channel layers disposed at intervals, and the gate structures cross the channel structure layer and surround the one or more channel layers.

The present disclosure also provides a fabrication method of a semiconductor structure. The method includes: providing a substrate, where gate structures are formed on the substrate, source-drain doped regions are formed in the substrate on two sides of each gate structure, and a bottom dielectric layer between adjacent gate structures is formed on the source-drain doped regions; forming liner metal layers in contact with the gate structures on top surfaces of the gate structures, where the liner metal layers are made of a pure metal; forming a top dielectric layer on the bottom dielectric layer to cover the liner metal layers; and forming gate plugs penetrating through the top dielectric layer and in contact with the liner metal layers using a first selective deposition process.

Optionally, the liner metal layers are made of a material including W, Ru, or Mo.

Optionally, the liner metal layers are formed by a second selective deposition process.

Optionally, the liner metal layers are made of a material including W; and parameters of the second selective deposition process include a reaction gas including WCl₅ and H₂.

Optionally, the second selective deposition process includes an atomic deposition process.

Optionally, the gate plugs are made of a material same as the liner metal layers.

Optionally, the gate plugs are made of a material including one or more of W or Ru.

Optionally, forming the gate plugs includes: forming gate contact holes penetrating through the top dielectric layer and exposing the liner metal layers; and forming gate plugs in the gate contact holes using the first selective deposition process, where the gate plugs are in contact with the liner metal layers.

Optionally, the first selective deposition process includes a selective chemical vapor deposition process.

Optionally, the gate structures are metal gate structures; and one metal gate structure includes a work function layer, or includes a metal electrode layer and a work function layer located on a bottom and sidewalls of the metal electrode layer.

Optionally, forming the top dielectric layer includes: forming a first dielectric layer on the bottom dielectric layer, covering the liner metal layers; and forming a second dielectric layer on the first dielectric layer. The method for forming the semiconductor structure further includes: after forming the first dielectric layer and before forming the second dielectric layer, forming source-drain interconnection layers which penetrate through the bottom dielectric layer and the first dielectric layer on tops of the source-drain doped regions and are in contact with the source-drain doped region. Forming the gate plugs penetrating through the top dielectric layer and in contact with the liner metal layers further includes: forming source-drain plugs penetrating through the second dielectric layer and in contact with the source-drain interconnection layers.

### Effective Benefits

Compared to existing technologies, the present disclosure has following benefits. In the semiconductor structure provided by the present disclosure, the liner metal layers may be disposed on the top surfaces of the gate structures. The liner metal layers may be made of pure metals, such that the tops of the gate structures may be surfaces of a single metal. The gate plugs may be formed by a first selective deposition process when forming the semiconductor structure. Therefore, the liner metal layers may be able to provide good forming interfaces and deposition substrates for forming the gate plugs by the first selective deposition process, and may be beneficial to deposition and growth of the materials of the gate plugs on the liner metal layers. Correspondingly, the process difficulty of forming the gate plugs may be reduced, the quality of the gate plugs and the performance of the formed device may be improved.

In the fabrication method of the semiconductor structure provided by the present disclosure, the liner metal layers may be formed on the top surfaces of the gate structures. The liner metal layers may be made of pure metals, such that the tops of the gate structures may be surfaces of a single metal. Therefore, the liner metal layers may be able to provide good forming interfaces and deposition substrates for forming the gate plugs by the first selective deposition process, and may be beneficial to deposition and growth of the materials of the gate plugs on the liner metal layers. Correspondingly, the process difficulty of forming the gate plugs by the first selective deposition process may be reduced, the quality of the gate plugs and the performance of the formed device may be improved.

### BRIEF DESCRIPTION OF THE DRAWINGS

FIG. 1 and FIG. 2 illustrate semiconductor structures corresponding to certain stages of a fabrication method of a semiconductor structure.

FIG. 3 illustrates an exemplary semiconductor structure according to various disclosed embodiments of the present disclosure.

FIG. 4 to FIG. 9 illustrate semiconductor structures corresponding to certain stages of an exemplary fabrication method of a semiconductor structure according to various disclosed embodiments of the present disclosure.

### DETAILED DESCRIPTION

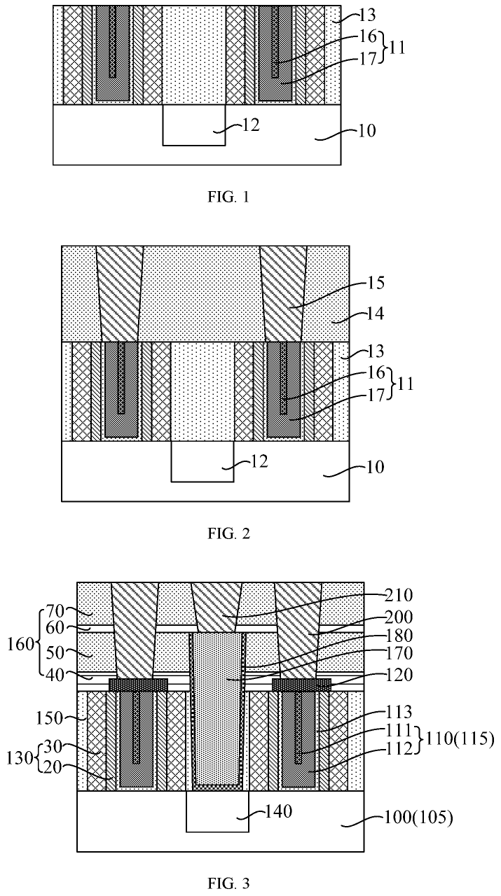

As described in the background, the performance of current semiconductor structures still needs to be improved. It will be analyzed and described below in combination with a fabrication method of a semiconductor structure. FIG. 1 and FIG. 2 illustrate semiconductor structures corresponding to certain stages of a fabrication method of a semiconductor structure.

As shown in FIG. 1, a substrate 10 is provided, and gate structures 11 are formed on the substrate 10. Source-drain doped regions 12 are formed in the substrate 10 on two sides of each gate structure 11. Bottom dielectric layers 13 are formed on the source-drain doped regions 12 between two adjacent gate structures 11.

As shown in FIG. 2, top dielectric layers 14 are formed on the bottom dielectric layers 13. Gate plugs 15 may be formed to penetrate through the top dielectric layers 14 and contact the gate structures 11, by a selective deposition process.

One gate structure 11 is usually a stacked structures of multiple film layers. For example, when the gate structure is a metal gate structure, the gate structure 11 usually includes a work function layer 17, or includes a metal electrode layer 16 and a work function layer 17 located on the sidewalls and bottom of the metal electrode layer 16. Therefore, the top surface of the gate structure 11 is a combination of multiple materials, that is, the top surface of the gate structure 11 is a complex combination of film layers.

In the process of forming the gate plugs 15 using the selective deposition process, since the top surface of the gate structure 11 is a complex combination of film layers, the growth rate of the selective deposition process on the surface is low, the growth is difficult, and the film quality of the formed gate plugs 15 is poor. In particular, when the gate structure 11 is a metal gate structure, the material of the work function layer 17 is usually a metal compound. In the selective deposition process, it is difficult to deposit on the metal compound, such that it is a greater challenge to form the gate plugs 15 using the selective deposition process.

To at least partially alleviate the above technical problems, the present disclosure provides a fabrication method of a semiconductor structure. The method may include: providing a substrate, including gate structures formed on the substrate, source-drain doped layers formed in the substrate on two sides of each gate structure, and a bottom dielectric layer formed between the adjacent gate structures on the source-drain doped regions; forming liner metal layers in contact with the gate structures on top surfaces of the gate structures; forming a top dielectric layer on the bottom dielectric layer, where the top dielectric layer covers the liner metal layers; and using a first selective deposition process to form gate plugs penetrating the top dielectric layer and being in contact with the liner metal layers.

In the present disclosure, the liner metal layers may be formed on the top surfaces of the gate structures. The liner metal layers may be made of pure metals, such that the tops of the gate structures may be surfaces of a single metal. Therefore, the liner metal layers may be able to provide good forming interfaces and deposition substrates for forming the gate plugs by the first selective deposition process, and may be beneficial to deposition and growth of the materials of the gate plugs on the liner metal layers. Correspondingly, the process difficulty of forming the gate plugs by the first selective deposition process may be reduced, the quality of the gate plugs and the performance of the formed device may be improved.

To at least partially alleviate the above technical problems, the present disclosure also provides a semiconductor structure. The semiconductor structure may include: a substrate, gate structures on the substrate, source-drain doped regions in the substrate on two sides of each gate structure; a bottom dielectric layer between adjacent gate structures and covering the source-drain doped regions; liner metal layers on top surfaces of the gate structures and in contact with the gate structures, which are made of a pure metal; a top dielectric layer on the bottom dielectric layer and covering the liner metal layers; and gate plugs penetrating through the top dielectric layer and in contact with the liner metal layers.

In the semiconductor structure provided by the present disclosure, the liner metal layers may be disposed on the top surfaces of the gate structures. The liner metal layers may be made of pure metals, such that the tops of the gate structures may be surfaces of a single metal. The gate plugs may be formed by a first selective deposition process when forming the semiconductor structure. Therefore, the liner metal layers may be able to provide good forming interfaces and deposition substrates for forming the gate plugs by the first selective deposition process, and may be beneficial to deposition and growth of the materials of the gate plugs on the liner metal layers. Correspondingly, the process difficulty of forming the gate plugs by the first selective deposition process may be reduced, the quality of the gate plugs and the performance of the formed device may be improved.

The semiconductor structure provided by the present disclosure will be described in following, to illustrate the implementation and benefits of the present disclosure.

FIG. 3 illustrates a semiconductor structure provided by one embodiment of the present disclosure.

As shown in FIG. 3, in one embodiment, the semiconductor structure may include: a substrate 100, gate structures 110 on the substrate 100, source-drain doped regions 140 in the substrate 100 on two sides of each gate structure 110; a bottom dielectric layer 150 between adjacent gate structures 110 and covering the source-drain doped regions 140; liner metal layers 120 on top surfaces of the gate structures 110 and in contact with the gate structures 110, which may be made of a pure metal; a top dielectric layer 160 on the bottom dielectric layer 150 and covering the liner metal layers 120; and gate plugs 200 penetrating through the top dielectric layer 160 and in contact with the liner metal layers 120.

The liner metal layers 120 may be disposed on the top surfaces of the gate structures 110. The liner metal layers 120 may be made of pure metals, such that the tops of the gate structures 110 may be surfaces of a single metal. The gate plugs 200 may be formed by a first selective deposition process when forming the semiconductor structure. Therefore, the liner metal layers 120 may be able to provide good forming interfaces and deposition substrates for forming the gate plugs 200 by the first selective deposition process, and may be beneficial to deposition and growth of the materials of the gate plugs 200 on the liner metal layers 120. Correspondingly, the process difficulty of forming the gate plugs 200 by the first selective deposition process may be reduced, the quality of the gate plugs 200 and the performance of the formed device may be improved.

The substrate 100 may be used to provide a process platform for the formation of the semiconductor structures.

In one embodiment, the substrate 100 may be used to form a fin field effect transistor (FinFET). The substrate 100 may be a three-dimensional substrate, including a base substrate (not shown) and fins 105 protruding from the substrate. The fins 105 may be used to provide conductive channels for the field effect transistor.

In this embodiment, the base substrate may be a silicon substrate. In other embodiments, the base substrate may be made of a material including germanium, silicon germanium, silicon carbide, gallium nitride, gallium arsenide, or indium gallium. The base substrate may also be a silicon-on-insulator substrate or a germanium-on-insulator substrate or other types of substrates.

The fins 105 may be made of a material including single crystalline silicon, germanium, silicon germanium, silicon carbide, gallium nitride, gallium arsenide or indium gallium. In the present embodiment, the fins 105 may be made of single crystal silicon.

In this embodiment, the fins 105 and the base substrate may have an integrated structure.

In other embodiments, the substrate 100 may also be used to form other types of transistors. For example, in one embodiment, the substrate 100 may be used to form a gate-all-around transistor and correspondingly the substrate 100 may include a base substrate, protruding portions protruding from the base substrate, and a channel structure layer located on the protruding portions. There may be a gap between the channel structure layer and the protruding portions. The channel structure layer may include one or more channel layers arranged at intervals. The channel layers may be used to provide conductive channels of the field effect transistor.

In one embodiment, the semiconductor structure may further include an isolation layer (not shown) surrounding the fins 105 formed on the base substrate. A top surface of the isolation layer may be lower than top surfaces of the fins 105 such that a portion of the fins 105 exposed by the isolation layer may be used as active fins. The active fins may be used to provide conductive channels for the field effect transistor.

The isolation layer may be used to isolate adjacent fins 105 and also to isolate the base substrate and the gate structures 110.

In one embodiment, the isolation layer may be a shallow trench isolation structure (STI). In one embodiment, the isolation layer may be made of silicon oxide. In other embodiments, the isolation layer may also be made of other insulating materials such as silicon nitride or silicon oxynitride.

When the field effect transistor operates, the gate structures 110 may be used to control the turning on and off of the conductive channels.

In one embodiment, the gate structures 110 may be disposed on the isolation layer, crossing the fins 105 and covering part of the top surfaces and sidewalls of the fins 105.

In other embodiments, when forming other types of transistors, such as when forming the all-gate-around transistor, the gate structures may span the channel structure layer and surround the channel layers.

In one embodiment, the gate structures 110 may be metal gate structures 115. Each metal gate structure 115 may include a work function layer 112. In some other embodiments, each metal gate structure 115 may include a metal electrode layer 111 and a work function layer 112 on a bottom and sidewalls of the metal electrode layer 111. In other embodiments, the gate structures 110 may be other types of gate structures. Therefore, the exposed top surfaces of the gate structures 110 may be top surfaces of work function layers 112, or top surfaces of work function layers 112 and top surfaces of the metal electrode layers 111.

In one embodiment, the gate structures 110 may be metal gate structures 115. Each metal gate structure 115 may include a metal electrode layer 111 and a work function layer 112 on a bottom and sidewalls of the metal electrode layer 111. Therefore, the exposed top surfaces of the gate structures 110 may be top surfaces of work function layers 112, or top surfaces of work function layers 112 and top surfaces of the metal electrode layers 111.

One work function layer 112 may be used to adjust a work function of one corresponding metal gate structure 115. The work function layer 112 may be made of a material including one or more of TiAl, TaAlN, TiAlN, MoN, TaCN, AlN, Ta, TiN, TaN, TaSiN, or TiSN. The metal electrode layer 111 may be made of a conductive material such as one or more of W, Al, Cu, Ag, Au, Pt, Ni, or Ti.

In one embodiment, the semiconductor structure may further include gate spacers 130, on sidewalls of the gate structures 110. The gate spacers 130 may be used to define the region for forming the source-drain doped regions 140, and also may protect the sidewalls of the gate structures 110.

The gate spacers 130 may be a single layer structure or a stacked structure. The gate spacer 130 may be made of any one or more of silicon oxide, silicon nitride, silicon carbide, silicon carbonitride, silicon oxynitride, silicon oxynitride, boron nitride or boron carbonitride.

In one embodiment, one gate spacer 130 may be a stacked structure, and may include a first spacer 20 located on the sidewall of one corresponding gate structure 110 and a second spacer 30 located on the sidewall of the side walls of the first spacer 20. The first spacer 20 and the second spacer 30 may be made of different materials. For example, the material of the first spacer 20 may be silicon oxide, and the material of the second spacer 30 may be silicon nitride.

In one embodiment, the semiconductor structure may further include a gate dielectric layer 133 between the gate structures 11 and the substrate 100.

The gate dielectric layer 113 may be used to electrically isolate the gate structures 110 and conductive channels.

In one embodiment, the gate dielectric layer 113 may be also located between the gate structures 110 and the gate spacers 130.

The gate dielectric layer 113 may be made of a material including one or more of SiO₂, SiON, HfO₂, ZrO₃, HfSiO, HfSiON, HfTaO, HfTiO, HfZrO, La₂O₃, or Al₂O₃.

When the device is operating, the source-drain doped regions 140 may be used as the source regions and drain regions of the field-effect transistor to provide carrier sources.

In one embodiment, the source-drain doped regions 140 may be located in the fins 105 on two sides of each gate structure 110. In other embodiments, the substrate may include a channel structure layer, and the source-drain doped regions may be located on two sides of the gate structure and may be in contact with the ends of the channel structure layer along the extension direction respectively.

In one embodiment, the source-drain doped regions 140 may include stress layers doped with ions, and the source-drain doped regions 150 may be also used to provide stress for the channels, thereby improving the carrier mobility of the channels.

When forming an NMOS transistor, the material of the source-drain doped regions 140 may be stress layers doped with N-type ions. The material of the stress layers may include Si or SiC. The stress layers may provide stretch stress for the channel regions of the NMOS transistor, improving the carrier mobility of the NMOS transistor. The N-type ions may include P ions, As ions or Sb ions. When forming a PMOS transistor, the material of the source-drain doped regions 140 may be stress layers doped with P-type ions. The material of the stress layers may include Si or SiGe. The stress layers may provide compressive stress for the channel regions of the PMOS transistor, improving the carrier mobility of the PMOS transistor. The P-type ions may include B ions, Ga ions or In ions.

The bottom dielectric layer 150 may be used to achieve isolation between adjacent devices. In this embodiment, the bottom dielectric layer 150 may be an interlayer dielectric layer (ILD). The material of the bottom dielectric layer 150 may be a dielectric material, such as silicon oxide, silicon oxynitride, etc. In this embodiment, the bottom dielectric layer 150 may expose the top surfaces of the gate structures 110.

The liner metal layers 120 may be made of pure metals, such that the tops of the gate structures 110 may be surfaces of a single metal. The gate plugs 200 may be formed by a first selective deposition process when forming the semiconductor structure. Therefore, the liner metal layers 120 may be able to provide good forming interfaces and deposition substrates for forming the gate plugs 200 by the first selective deposition process, and may be beneficial to deposition and growth of the materials of the gate plugs 200 on the liner metal layers 120. Correspondingly, the process difficulty of forming the gate plugs 200 by the first selective deposition process may be reduced, the quality of the gate plugs 200 and the performance of the formed device may be improved.

Further, in the field of semiconductor technology, compared with using a selective deposition process to deposit gate plug materials on metal compounds, it may be easier to deposit and grow materials on pure metals using a selective deposition process. In this embodiment, the liner metal layers 120 may be made of a material including a pure metal, which facilitates the formation of the gate plugs 200 on the liner metal layer 120 using the first selective deposition process.

As an example, in one embodiment, the liner metal layers 120 may be made of a material including tungsten (W), ruthenium (Ru) or molybdenum (Mo). In various embodiments of the present disclosure, the material of the liner metal layers is not limited thereto, and any metal material that is able to facilitate the deposition and growth of the gate plugs by the first selective deposition process may be selected.

In one embodiment, during the formation process of the semiconductor structure, when forming the liner metal layers 120, as the deposition thickness of the material of the liner metal layers 120 on the top surface of the gate structures 110 gradually increases, the material of the liner metal layers 120 may also extend to the periphery of the top surfaces of the gate structures 110. Therefore, the liner metal layers 120 may be also located on the top surfaces of the gate dielectric layers 113 and a portion of top surfaces of the spacers 130.

The thickness of the liner metal layers 120 should not be too small, nor should it be too large. When the thickness of the liner metal layers 120 is too small, the film continuity of the liner metal layers 120 may be poor. When the thickness of the liner metal layers 120 is too large, unnecessary materials and time may easily be wasted. Also, the liner metal layers 120 may grow too much toward two sides of each gate structure 110 easily, which can easily increase the risk of leakage. Therefore, the thickness of the liner metal layers 120 may be set to about 1.5 nm to 3 nm, for example: 2 nm, 2.3 nm, 2.5 nm, 2.8 nm, etc.

In one embodiment, the material of the liner metal layers 120 may contain chlorine element.

In one embodiment, the liner metal layers 120 may be made of tungsten, and the material of the liner metal layers 120 may contain chlorine. A second selective deposition process may be used to form the liner metal layers 120. The second selective deposition process may use a reaction gas including WCl5.

During the formation of the liner metal layers 120, the second selective deposition process may use the difference in the growth of the material of the liner metal layers 120 on metallic materials and non-metal materials to selectively form the liner metal layers 120 only on the top surfaces of the gate structures 110, while the material of the liner metal layers 120 may not be formed on the top surfaces of the gate spacers 130 or the bottom dielectric layer 150. Therefore, the need of the patterning or etching processes may be eliminated, simplifying the formation process of the liner metal layers 120. The metal materials may include pure metal materials, metal alloy materials, or metal compound materials.

WCl5 may be used as the reactant for selective deposition of tungsten. WCl5 gas has lower requirements on the deposition substrate of the selective deposition process, which is beneficial to the deposition and growth of tungsten on the top surfaces of the gate structures 110 with a complex film structure. That WCl5 gas has lower requirements on the deposition substrate of the selective deposition process means that when WCl5 is used as the reactive gas, a complex film layer structure may be used as a deposition substrate without requiring the deposition substrate to be a single film layer structure.

In the semiconductor field, tungsten fluoride gas is usually used as the reactive gas for selective deposition of tungsten. In the process of selectively depositing tungsten using tungsten fluoride as the reactive gas, tungsten fluoride may easily corrode the work function layers 112 of the gate structures 110, resulting in damage to the gate structures 110. Therefore, the structural integrity of the gate structure 110 cannot be guaranteed, and the contact performance between tungsten and the gate structures may be poor. Correspondingly, it may also be difficult to deposit tungsten on the work function layers 112 of the gate structures 110.

In this embodiment, the reactive gas of the second selective deposition process may include WCl5, thereby avoiding the use of tungsten fluoride as the reactive gas for selective deposition of tungsten, which is beneficial to the deposition of tungsten on the top surfaces of the gate structures 110. Especially, this may be beneficial to the deposition of tungsten on the work function layers 112.

The top dielectric layer 160 may be used to achieve electrical isolation between adjacent gate plugs 200.

The top dielectric layer 160 may be made of a dielectric material. For example, the material of the top dielectric layer 160 may include one or more of a low-k dielectric material (a low-k dielectric material refers to a dielectric material with a relative dielectric constant larger than or equal to 2.6 and less than or equal to 3.9), an ultra-low-k dielectric material (ultra-low-k dielectric materials refer to dielectric materials with a relative dielectric constant less than 2.6), silicon oxide, silicon nitride, or silicon oxynitride.

The top dielectric layer 160 may be a single-layer structure or a stacked-layer structure.

In one embodiment, the top dielectric layer 160 may include a first dielectric layer 50 located on the bottom dielectric layer 150 and covering the liner metal layer 120, and a second dielectric layer 70 located on the first dielectric layer 50.

In one embodiment, the semiconductor structure may further include source-drain interconnection layers 170, penetrating the bottom dielectric layer 150 on top of the source-drain doped region 140 and the first dielectric layer 50. One source-drain interconnection layer 170 may be in contact with one corresponding source-drain doped region 140.

The source-drain interconnection layers 170 may be used to realize electrical connection between the source-drain doped regions 140 and external circuits.

The source-drain interconnection layers 170 may be made of a conductive material, such as one or more of W, Co, Ru, Cu or Al. As an example, in one embodiment, the material of the source-drain interconnection layers 170 may be W.

In one embodiment, an anti-diffusion barrier layer 180 may be further formed on the sidewalls and bottom of the source-drain interconnection layers 170. The anti-diffusion barrier layer 180 may be used to prevent the material of the source-drain interconnection layers 170 from diffusing into the bottom dielectric layer 150 or the first dielectric layer 50, thereby alleviating the problem of electromigration.

In one embodiment, the anti-diffusion barrier layer 180 may be made of a material including one or more of Ta, Ti, TaN or TiN.

The first dielectric layer 50 may be also used to achieve electrical isolation between adjacent source-drain interconnection layers 170.

In one embodiment, the top dielectric layer 160 may further include: a first etch stop layer 40 located between the bottom dielectric layer 150 and the first dielectric layer 50, and between the liner metal layers 120 and the first dielectric layer 50. The first etch stop layer 40 may be also located between the gate spacers 130 and the first dielectric layer 50.

During the process of forming the gate plugs 200 penetrating through the first dielectric layer 50 and the second dielectric layer 70 and in contact with the liner metal layers 120, the first etch stop layer 40 may be used to temporarily define the etch stop position, reducing the probability of the liner metal layers 120 to be damaged. The first etch stop layer 40 may be also used to encapsulate the liner metal layers 120 and the top surfaces of the gate structures 110, to prevent the liner metal layers 120 and the top surfaces of the gate structures 110 from being damaged by the external process environment.

The first etch stop layer 40 may be made of a material that has etching selectivity between the first dielectric layer 50 and the second dielectric layer 70. As an example, in one embodiment, the first etch stop layer 40 may be made of silicon nitride.

In one embodiment, the top dielectric layer 160 may further include a second etch stop layer 60 located between the first dielectric layer 50 and the second dielectric layer 70. The second etch stop layer 60 may be also located between the source-drain interconnection layers 170 and the second dielectric layer 70.

In one embodiment, the semiconductor structure may further include source-drain plugs penetrating through the second dielectric layer 70 and in contact with the source-drain interconnection layers 170. The second etch stop layer 60 may be used to temporarily define the etch stop position when forming the source-drain plugs, to reduce the probability of damage to the source-drain interconnection layers 170.

The gate plugs 200 may be used to realize electrical connection between the gate structures 110 and external circuits.

In one embodiment, the gate plugs 200 may be made of a conductive material including one or more of W and Ru. In one embodiment, the material of the gate plugs 200 may be the same as the material of the liner metal layers 120. Therefore, the first selective deposition process may be easy to deposit and grow on the liner metal layers 120, further reducing the difficulty of forming the gate plugs 200 in the first selective deposition process.

In one embodiment, the semiconductor structure may further include: source-drain plugs 210 that penetrate through the second dielectric layer 70 and are in contact with the source-drain interconnection layers 170.

The source-drain plugs 210 may be used to realize electrical connection between the source-drain interconnection layers 170 and external circuits.

The source-drain plugs 210 may be made of a conductive material including one or more of W, Co, Ru, Cu or Al. In one embodiment, the source-drain plugs 210 may be made of the same material as the gate plugs 200.

In this embodiment, the source-drain plugs 210 may be made of the same material as the gate plugs 200. Therefore, during the formation process of the semiconductor structure, the source-drain plugs 210 and the gate plugs 200 may be formed in the same step, thereby improving process integration and simplifying process steps.

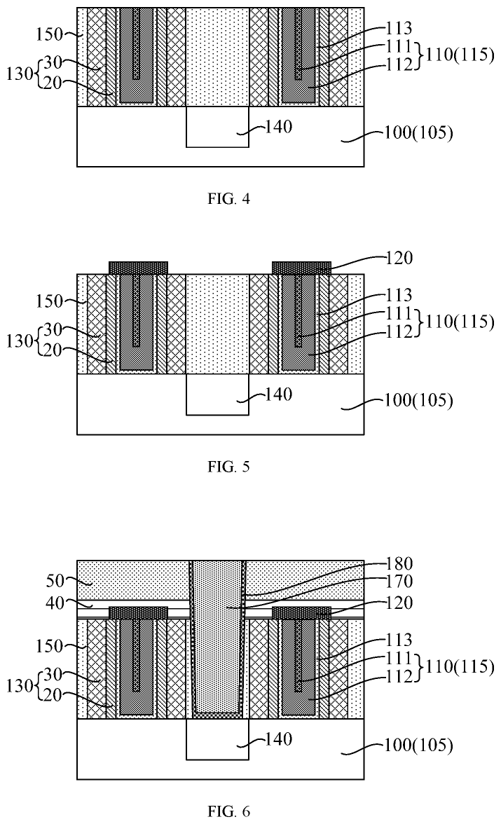

The present disclosure also provides a fabrication method of a semiconductor structure. FIG. 4 to FIG. 9 illustrate semiconductor structures corresponding to certain stages of the method provided by one embodiment of the present disclosure.

The fabrication method of a semiconductor structure will be described following with reference to the drawings.

As shown in FIG. 4, s substrate 100 may be provided. Gate structures 110 may be formed on the substrate 100, and source-drain doped regions 140 may be formed in the substrate 100 on two sides of each gate structure 110. A bottom dielectric layer 150 may be formed on the source-drain doped regions 140 between adjacent gate structures 110.

The substrate 100 may be used to provide a process platform for the formation of the semiconductor structures.

In one embodiment, the substrate 100 may be used to form a fin field effect transistor (FinFET). The substrate 100 may be a three-dimensional substrate, including a base substrate (not shown) and fins 105 protruding from the substrate. The fins 105 may be used to provide conductive channels for the field effect transistor.

In this embodiment, the base substrate may be a silicon substrate. In other embodiments, the base substrate may be made of a material including germanium, silicon germanium, silicon carbide, gallium nitride, gallium arsenide, or indium gallium. The base substrate may also be a silicon-on-insulator substrate or a germanium-on-insulator substrate or other types of substrates.

The fins 105 may be made of a material including single crystalline silicon, germanium, silicon germanium, silicon carbide, gallium nitride, gallium arsenide or indium gallium. In the present embodiment, the fins 105 may be made of single crystal silicon.

In this embodiment, the fins 105 and the base substrate may have an integrated structure.

In other embodiments, the substrate 100 may also be used to form other types of transistors. For example, in one embodiment, the substrate 100 may be used to form a gate-all-around transistor and correspondingly the substrate 100 may include a base substrate, protruding portions protruding from the base substrate, and a channel structure layer located on the protruding portions. There may be a gap between the channel structure layer and the protruding portions. The channel structure layer may include one or more channel layers arranged at intervals. The channel layers may be used to provide conductive channels of the field effect transistor.

In one embodiment, the semiconductor structure may further include an isolation layer (not shown) surrounding the fins 105 formed on the base substrate. A top surface of the isolation layer may be lower than top surfaces of the fins 105 such that a portion of the fins 105 exposed by the isolation layer may be used as active fins. The active fins may be used to provide conductive channels for the field effect transistor.

The isolation layer may be used to isolate adjacent fins 105 and also to isolate the base substrate and the gate structures 110.

In one embodiment, the isolation layer may be a shallow trench isolation structure (STI). In one embodiment, the isolation layer may be made of silicon oxide. In other embodiments, the isolation layer may also be made of other insulating materials such as silicon nitride or silicon oxynitride.

When the field effect transistor operates, the gate structures 110 may be used to control the turning on and off of the conductive channels.

In one embodiment, the gate structures 110 may be disposed on the isolation layer, crossing the fins 105 and covering part of the top surfaces and sidewalls of the fins 105.

In other embodiments, when forming other types of transistors, such as when forming the gate-all-around transistor, the gate structures may span the channel structure layer and surround the channel layers.

In one embodiment, the gate structures 110 may be metal gate structures 115. Each metal gate structure 115 may include a work function layer 112. In some other embodiments, each metal gate structure 115 may include a metal electrode layer 111 and a work function layer 112 on a bottom and sidewalls of the metal electrode layer 111. In other embodiments, the gate structures 110 may be other types of gate structures. Therefore, the exposed top surfaces of the gate structures 110 may be top surfaces of work function layers 112, or top surfaces of work function layers 112 and top surfaces of the metal electrode layers 111.

In one embodiment, each metal gate structure 115 may include a metal electrode layer 111 and a work function layer 112 on a bottom and sidewalls of the metal electrode layer 111. Therefore, the exposed top surfaces of the gate structures 110 may be top surfaces of work function layers 112, or top surfaces of work function layers 112 and top surfaces of the metal electrode layers 111.

One work function layer 112 may be used to adjust a work function of one corresponding metal gate structure 115. The work function layer 112 may be made of a material including one or more of TiAl, TaAlN, TiAlN, MoN, TaCN, AlN, Ta, TiN, TaN, TaSiN, or TiSN.

The metal electrode layer 111 may be made of a conducive material such as one or more of W, Al, Cu, Ag, Au, Pt, Ni, or Ti.

In one embodiment, gate spacers 130 may be formed on sidewalls of the gate structures 110.

The gate spacers 130 may be used to define the region for forming the source-drain doped regions 140, and also may protect the sidewalls of the gate structures 110.

The gate spacers 130 may be single layer structures or stacked structures. The gate spacer 130 may be made of any one or more of silicon oxide, silicon nitride, silicon carbide, silicon carbonitride, silicon oxynitride, silicon oxynitride, boron nitride or boron carbonitride.

In one embodiment, one gate spacer 130 may be a stacked structure, and may include a first spacer 20 located on the sidewall of one corresponding gate structure 110 and a second spacer 30 located on the sidewall of the first spacer 20. The first spacer 20 and the second spacer 30 may be made of different materials. For example, the material of the first spacer 20 may be silicon oxide, and the material of the second spacer 30 may be silicon nitride.

In one embodiment, a gate dielectric layer 133 may be formed between the gate structures 11 and the substrate 100. The gate dielectric layer 113 may be used to electrically isolate the gate structures 110 and conductive channels.

In one embodiment, the gate dielectric layer 113 may be also located between the gate structures 110 and the gate spacers 130.

The gate dielectric layer 113 may be made of a material including one or more of SiO₂, SiON, HfO₂, ZrO₃, HfSiO, HfSiON, HfTaO, HfTiO, HfZrO, La₂O₃, or Al₂O₃.

When the device is operating, the source-drain doped regions 140 may be used as the source regions or drain regions of the field-effect transistor to provide carrier sources.

In one embodiment, the source-drain doped regions 140 may be located in the fins 105 on two sides of each gate structure 110. In other embodiments, the substrate may include a channel structure layer, and the source-drain doped regions may be located on two sides of the gate structure and may be in contact with the ends of the channel structure layer along the extension direction respectively.

In one embodiment, the source-drain doped regions 140 may include stress layers doped with ions, and the source-drain doped regions 150 may be also used to provide stress for the channels, thereby improving the carrier mobility of the channels.

When forming an NMOS transistor, the material of the source-drain doped regions 140 may be stress layers doped with N-type ions. The material of the stress layers may include Si or SiC. The stress layers may provide stretch stress for the channel regions of the NMOS transistor, improving the carrier mobility of the NMOS transistor. The N-type ions may include P ions, As ions or Sb ions. When forming a PMOS transistor, the material of the source-drain doped regions 140 may be stress layers doped with P-type ions. The material of the stress layers may include Si or SiGe. The stress layers may provide compressive stress for the channel regions of the PMOS transistor, improving the carrier mobility of the PMOS transistor. The P-type ions may include B ions, Ga ions or In ions.

The bottom dielectric layer 150 may be used to achieve isolation between adjacent devices. In this embodiment, the bottom dielectric layer 150 may be an interlayer dielectric layer (ILD). The material of the bottom dielectric layer 150 may be a dielectric material, such as silicon oxide, silicon oxynitride, etc. In this embodiment, the bottom dielectric layer 150 may expose the top surfaces of the gate structures 110.

As shown in FIG. 5, liner metal layers 120 may be formed on top surfaces of the gate structures 110 and in contact with the gate structures 110. The liner metal layers 120 may be made of pure metals.

The liner metal layers 120 may be disposed on the top surfaces of the gate structures 110. The liner metal layers 120 may be made of pure metals, such that the tops of the gate structures 110 may be surfaces of a single metal material. Therefore, the liner metal layers 120 may be able to provide good forming interfaces and deposition substrates for forming the gate plugs 200 by the first selective deposition process, and may be beneficial to deposition and growth of the materials of the gate plugs 200 on the liner metal layers 120. Correspondingly, the process difficulty of forming the gate plugs 200 by the first selective deposition process may be reduced, the quality of the gate plugs 200 and the performance of the formed device may be improved.

Further, in the field of semiconductor technology, compared with using a selective deposition process to deposit gate plug materials on metal compounds, it may be easier to deposit and grow materials on pure metals using a selective deposition process. In this embodiment, the liner metal layers 120 may be made of a material including a pure metal, which facilitates the formation of the gate plugs 200 on the liner metal layer 120 using the first selective deposition process.

As an example, in one embodiment, the liner metal layers 120 may be made of a material including tungsten (W), ruthenium (Ru) or molybdenum (Mo). In various embodiments of the present disclosure, the material of the liner metal layers is not limited thereto, and any metal material that is able to facilitate the deposition and growth of the gate plugs by the first selective deposition process may be selected.

In one embodiment, when forming the liner metal layers 120, as the deposition thickness of the material of the liner metal layers 120 on the top surface of the gate structures 110 gradually increases, the material of the liner metal layers 120 may also extend to the periphery of the top surfaces of the gate structures 110. Therefore, the liner metal layers 120 may be also located on the top surfaces of the gate dielectric layers 113 and a portion of top surfaces of the spacers 130.

The thickness of the liner metal layers 120 should not be too small, nor should it be too large. When the thickness of the liner metal layers 120 is too small, the film continuity of the liner metal layers 120 may be poor. When the thickness of the liner metal layers 120 is too large, unnecessary materials and time may easily be wasted. Also, the liner metal layers 120 may grow too much toward two sides of each gate structure 110 easily, which can easily increase the risk of leakage. Therefore, the thickness of the liner metal layers 120 may be set to about 1.5 nm to 3 nm, for example: 2 nm, 2.3 nm, 2.5 nm, 2.8 nm, etc.

In one embodiment, the liner metal layers 120 may be formed by a second selective deposition process. The second selective deposition process may use the difference in the growth of the material of the liner metal layers 120 on metallic materials and non-metal materials to selectively form the liner metal layers 120 only on the top surfaces of the gate structures 110, while the material of the liner metal layers 120 may not be formed on the top surfaces of the gate spacers 130 or the bottom dielectric layer 150. Therefore, the needs of the patterning or etching processes may be eliminated, simplifying the formation process of the liner metal layers 120. The metal materials may include pure metal materials, metal alloy materials, or metal compound materials.

In one embodiment, the liner metal layers 120 may be made of tungsten, and the parameters of the second selective deposition process may be a reaction gas including WCl5 and H₂.

WCl5 may be used as the reactant for selective deposition of tungsten. WCl5 gas has lower requirements on the deposition substrate of the selective deposition process, which is beneficial to the deposition and growth of tungsten on the top surfaces of the gate structures 110 with a complex film structure. That WCl5 gas has lower requirements on the deposition substrate of the selective deposition process means that when WCl5 is used as the reactive gas, a complex film layer structure may be used as a deposition substrate without requiring the deposition substrate to be a single film layer structure.

In the semiconductor field, tungsten fluoride gas is usually used as the reactive gas for selective deposition of tungsten. In the process of selectively depositing tungsten using tungsten fluoride as the reactive gas, tungsten fluoride may easily corrode the work function layers 112 of the gate structures 110, resulting in damage to the gate structures 110. Therefore, the structural integrity of the gate structure 110 cannot be guaranteed, and the contact performance between tungsten and the gate structures may be poor. Correspondingly, it may also be difficult to deposit tungsten on the work function layers 112 of the gate structures 110.

In this embodiment, the reactive gas of the second selective deposition process may include WCl5, thereby avoiding the use of tungsten fluoride as the reactive gas for selective deposition of tungsten, which is beneficial to the deposition of tungsten on the top surfaces of the gate structures 110. Especially, this may be beneficial to the deposition of tungsten on the work function layers 112.

In one embodiment, the second selective deposition process may be an atomic layer deposition process. The atomic layer deposition process is a self-limiting reaction process based on the atomic layer deposition process. The deposited film is able to reach the thickness of a single layer of atoms. Since the atomic layer deposition process can accurately deposit one atomic layer in each cycle, the atomic layer deposition process may be beneficial to the accurate control of the thickness of the liner metal layers 120. The film prepared by the atomic layer deposition process also has the advantages of good bonding strength and high thickness consistency.

The above embodiment of forming the liner metal layers 120 is only used as an example to illustrate the present disclosure, and the method of forming the liner metal layers 120 is not limited thereto. For example, in other embodiments, forming the liner metal layers may include: forming a liner metal material layer on the bottom dielectric layer and the gate structures; removing a portion of the liner metal material layer located on the bottom dielectric layer and preserving another portion of the liner metal material layer on the top surfaces of the gate structures as the liner metal layers.

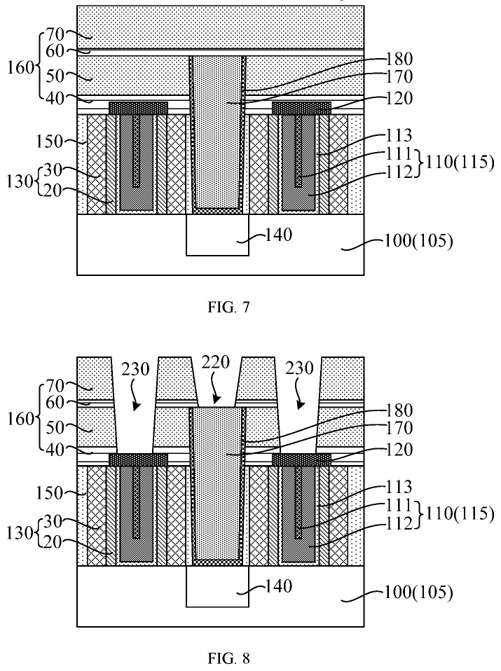

As shown in FIG. 6 and FIG. 7, a top dielectric layer 160 may be formed on the bottom dielectric layer 150. The top dielectric layer may cover the liner metal layers 120.

Gate plugs penetrating the top dielectric layer 160 and in contact with the liner metal layers 120 may be formed subsequently. The top dielectric layer 160 may be used to achieve electrical isolation between adjacent gate plugs.

The top dielectric layer 160 may be made of a dielectric material. For example, the material of the top dielectric layer 160 may include one or more of a low-k dielectric material (a low-k dielectric material refers to a dielectric material with a relative dielectric constant larger than or equal to 2.6 and less than or equal to 3.9), an ultra-low-k dielectric material (ultra-low-k dielectric materials refer to dielectric materials with a relative dielectric constant less than 2.6), silicon oxide, silicon nitride, or silicon oxynitride.

In one embodiment, the top dielectric layer 160 may be formed by following processes.

As shown in FIG. 6, a first dielectric layer 50 may be formed on the bottom dielectric layer 150 to cover the liner metal layers 120.

In one embodiment, before forming the first dielectric layer 50 on the bottom dielectric layer 150, an etch stop layer 40 may be formed on the bottom dielectric layer 150 to cover the liner metal layers 120.

During the process of forming the gate plugs 200 penetrating through the first dielectric layer 50 and the second dielectric layer 70 and in contact with the liner metal layers 120, the first etch stop layer 40 may be used to temporarily define the etch stop position, reducing the probability of the liner metal layers 120 to be damaged. The first etch stop layer 40 may be also used to encapsulate the liner metal layers 120 and the top surfaces of the gate structures 110, to prevent the liner metal layers 120 and the top surfaces of the gate structures 110 from being damaged by the external process environment.

The first etch stop layer 40 may be made of a material that has etching selectivity between the first dielectric layer 50 and the second dielectric layer 70. As an example, in one embodiment, the first etch stop layer 40 may be made of silicon nitride.

As shown in FIG. 6, the method may further include: after forming the first dielectric layer 50, source-drain interconnection layers 170 penetrating the bottom dielectric layer 150 on tops of the source-drain doped region 140 and the first dielectric layer 50 may be formed. One source-drain interconnection layer 170 may be in contact with one corresponding source-drain doped region 140.

The source-drain interconnection layers 170 may be used to realize electrical connection between the source-drain doped regions 140 and external circuits.

The source-drain interconnection layers 170 may be made of a conductive material, such as one or more of W, Co, Ru, Cu or Al. As an example, in one embodiment, the material of the source-drain interconnection layers 170 may be W.

The source-drain interconnection layers 170 may be formed by: forming source-drain interconnection grooves (not shown in the figures) penetrating the bottom dielectric layer 150 on tops of the source-drain doped region 140 and the first dielectric layer 50, where the source-drain interconnection grooves may expose the source-drain doped regions 140; and forming the source-drain interconnection layers 170 in the source-drain interconnection grooves.

In one embodiment, after forming the source-drain interconnection grooves and before forming the source-drain interconnection layers 170 in the source-drain interconnection grooves, the method may further include forming an anti-diffusion layer 180 on bottoms and sidewalls of the source-drain interconnection grooves. The anti-diffusion barrier layer 180 may be used to prevent the material of the source-drain interconnection layers 170 from diffusing into the bottom dielectric layer 150 or the first dielectric layer 50, thereby alleviating the problem of electromigration.

In one embodiment, the anti-diffusion barrier layer 180 may be made of a material including one or more of Ta, Ti, TaN or TiN.

In one embodiment, after forming the first dielectric layer 50, the method may further include: forming a second etch stop layer 60 on the first dielectric layer 60. The second etch stop layer 60 may cover the source-drain interconnection layers 170. When forming source-drain plugs penetrating through the second dielectric layer 70 and in contact with the source-drain interconnection layers 170 subsequently, the second etching stop layer 60 may be used to temporarily define the etching stop position, to reduce the probability of damage to the source-drain interconnection layers 170.

As shown in FIG. 7, a second dielectric layer 70 may be formed on the first dielectric layer 50.

In one embodiment, the second dielectric layer 70 may be formed on the second etch stop layer 60.

In the present embodiment, the top dielectric layer 160 may be a stacked structure. In some other embodiments, the top dielectric layer 160 may be a single-layer structure.

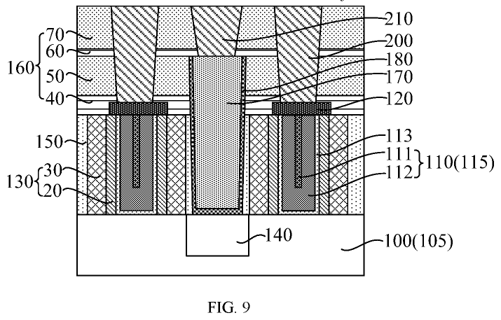

As shown in FIG. 8 and FIG. 9, gate plugs 200 penetrating through the top dielectric layer 160 and in contact with the liner metal layers 120 may be formed by a first selective deposition process.

The gate plugs 200 may be used to realize electrical connection between the gate structures 110 and external circuits.

The liner metal layers 120 may be disposed on the top surfaces of the gate structures 110. The liner metal layers 120 may be made of pure metals, such that the tops of the gate structures 110 may be surfaces of a single metal material. Therefore, the liner metal layers 120 may be able to provide good forming interfaces and deposition substrates for forming the gate plugs 200 by the first selective deposition process, and may be beneficial to deposition and growth of the materials of the gate plugs 200 on the liner metal layers 120. Correspondingly, the process difficulty of forming the gate plugs 200 by the first selective deposition process may be reduced, the quality of the gate plugs 200 and the performance of the formed device may be improved.

In one embodiment, the gate plugs 200 may be made of a conductive material including one or more of W and Ru. In one embodiment, the material of the gate plugs 200 may be the same as the material of the liner metal layers 120. Therefore, the first selective deposition process may be easy to deposit and grow on the liner metal layers 120, further reducing the difficulty of forming the gate plugs 200 in the first selective deposition process.

In one embodiment, when forming the gate plugs 200, the method may further include forming source-drain plugs penetrating through the second dielectric layer 70 and in contact with the source-drain interconnection layers 170. The source-drain plugs 210 may be used to achieve the electrical connection between the source-drain interconnection layers 170 and external circuits.

The source-drain plugs 210 may be made of a conductive material including one or more of W, Co, Ru, Cu or Al. In one embodiment, the source-drain plugs 210 may be made of a material same as the gate plug.

In one embodiment, forming the gate plugs 200 may include following processes.

As shown in FIG. 8, gate contact holes 230 penetrating through the top dielectric layer 160 may be formed. The gate contact holes 230 may expose the liner metal layers 120.

The gate contact holes 230 may be used to provide space positions for forming the gate plugs.

In one embodiment, when forming the gate contact holes 230, the method may further include forming source-drain contact holes 220 penetrating through the second dielectric layer 70 to expose the source-drain interconnection layers 170.

The source-drain contact holes 220 may provide space positions for forming the source-drain plugs.

As shown in FIG. 9, the gate plugs 200 in contact with the liner metal layers 120 may be formed in the gate contact holes 230 using the first selective deposition process.

By using the first selective deposition process, the material of the gate plugs 200 may be only formed on the liner metal layers 120 exposed by the gate contact holes 230 selectively. Therefore, there may be no need to remove the material of the gate plugs 200 on the top surface of the top dielectric layer 160, simplifying the fabrication process.

Compared with existing barrier layer wire fabrication process, using the first selective deposition process may achieve bottom-up metal-to-metal deposition, which is beneficial to maximizing the volume of the gate plugs 200. Therefore, the resistivity of the gate plugs 200 may be significantly improved. A lower resistivity may increase the device density and extend two-dimensional scaling.

In one embodiment, the first selective deposition process may be used to form the gate plugs 200 in the gate contact holes 230 and the source-drain plugs 210 in the source-drain contact holes.

By using the first selective deposition process to form the gate plugs 200 and the source-drain plugs 210 in the same step, process compatibility and process integration may be improved.

During the first selective deposition process, the incubation time difference between the materials of the gate plug 200 and the source-drain plug 210 on the metal material and on the non-metal material is utilized, conductive materials may be only deposited in the gate contact holes 230 and the source-drain contact holes 220.

As an example, in one embodiment, the first selective deposition process may be a selective chemical vapor deposition process.

In one embodiment, the material of the gate plugs 200 and the source-drain plugs 210 may be tungsten, and the first selective deposition process may be a selective tungsten chemical vapor deposition (Selective W CVD) process.

The source-drain plugs 210 and the source-drain interconnection layers 170 may be used to form a source-drain contact structures to achieve electrical connection between the source-drain doped regions and external circuits.

It should be noted that the above steps of forming the source-drain contact structures are only an example, and the steps of forming the source-drain contact structures are not limited to this. For example: in other embodiments, the step of forming the source-drain contact structures may include: before forming the top dielectric layer, forming the source-drain interconnection layers that is in contact with the source-drain doped regions in the bottom dielectric layer; and, after forming the top dielectric layer, forming the source-drain plugs in contact with the source-drain interconnection layers in the top dielectric layer.

The embodiments disclosed herein are exemplary only. Other applications, advantages, alternations, modifications, or equivalents to the disclosed embodiments are obvious to those skilled in the art and are intended to be encompassed within the scope of the present disclosure.

1. A semiconductor structure, comprising:
a substrate;
gate structures on the substrate;
source-drain doped regions in the substrate on two sides of each gate structure;
a bottom dielectric layer between adjacent gate structures and covering the source-drain doped regions;
liner metal layers on top surfaces of the gate structures and in contact with the gate structures, wherein the liner metal layers are made of a material including a pure metal;
a top dielectric layer on the bottom dielectric layer and covering the liner metal layers; and
gate plugs, penetrating through the top dielectric layer and in contact with the liner metal layers.

2. The semiconductor structure according to claim 1, wherein:
the liner metal layers are made of a material including W, Ru, or Mo.

3. The semiconductor structure according to claim 1, wherein:
a thickness of the liner metal layers is about 1.5 nm to about 3 nm.

4. The semiconductor structure according to claim 1, wherein:
the liner metal layers include chlorine element.

5. The semiconductor structure according to claim 1, wherein:
the gate plugs are made of a material same as the liner metal layers.

6. The semiconductor structure according to claim 1, wherein:
the gate plugs are made of a material including one or more of W or Ru.

7. The semiconductor structure according to claim 1, wherein:
the gate structures are metal gate structures; and
one metal gate structure includes a work function layer, or includes a metal electrode layer and a work function layer located on a bottom and sidewalls of the metal electrode layer.

8. The semiconductor structure according to claim 7, wherein:
the work function layer is made of a material including one or more of TiA, TaAlN, TiAlN, MoN, TaCN, AlN, Ta, TiN, TaN, TaSiN, or TiSiN; and
the metal electrode layer is made of a material including one or more of W, Al, Cu, Ag, Au, Pt, Ni, or Ti.

9. The semiconductor structure according to claim 7, further including:
gate spacers on sidewalls of the gate structures; and
gate dielectric layers between the gate structures and the substrate.

10. The semiconductor structure according to claim 1, wherein:
the top dielectric layer includes: a first dielectric layer on the bottom dielectric layer and covering the liner metal layers; and a second dielectric layer on the first dielectric layer;
the semiconductor structure further includes: source-drain interconnection layers which penetrate through the bottom dielectric layer and the first dielectric layer on tops of the source-drain doped regions, and are in contact with the source-drain doped region; and source-drain plugs, penetrating through the second dielectric layer and in contact with the source-drain interconnection layers.

11. The semiconductor structure according to claim 1, wherein:
the substrate includes fins, wherein the gate structures cross the fins and the source-drain doped regions are located in the fins on two sides of each gate structure; or
the substrate includes a channel structure layer, wherein the channel structure layer includes one or more channel layers disposed at intervals, and the gate structures cross the channel structure layer and surround the one or more channel layers.

12. A method for forming a semiconductor structure, comprising:
providing a substrate, wherein gate structures are formed on the substrate, source-drain doped regions are formed in the substrate on two sides of each gate structure, and a bottom dielectric layer between adjacent gate structures is formed on the source-drain doped regions;
forming liner metal layers in contact with the gate structures on top surfaces of the gate structures, wherein the liner metal layers are made of a pure metal;
forming a top dielectric layer on the bottom dielectric layer to cover the liner metal layers; and
forming gate plugs penetrating through the top dielectric layer and in contact with the liner metal layers using a first selective deposition process.

13. The method for forming the semiconductor structure according to claim 12, wherein:
the liner metal layers are made of a material including W, Ru, or Mo.

14. The method for forming the semiconductor structure according to claim 12, wherein:
the liner metal layers are formed by a second selective deposition process.

15. The method for forming the semiconductor structure according to claim 14, wherein:
the liner metal layers are made of a material including W; and
parameters of the second selective deposition process include a reaction gas including WCl₅ and H₂.

16. The method for forming the semiconductor structure according to claim 14, wherein:
the second selective deposition process includes an atomic deposition process.

17. The method for forming the semiconductor structure according to claim 12, wherein:
the gate plugs are made of a material same as the liner metal layers.

18. The method for forming the semiconductor structure according to claim 12, wherein:
the gate plugs are made of a material including one or more of W or Ru.

19. The method for forming the semiconductor structure according to claim 12, wherein forming the gate plugs includes:
forming gate contact holes penetrating through the top dielectric layer, wherein the gate contact holes expose the liner metal layers; and
forming gate plugs in the gate contact holes using the first selective deposition process, wherein the gate plugs are in contact with the liner metal layers.

20. The method for forming the semiconductor structure according to claim 12, wherein:
the first selective deposition process includes a selective chemical vapor deposition process.

21. (canceled)

22. (canceled)
